(19) United States
(12) Patent Application Publication
(10) Pub. No.: US 2021/0028771 A1
(43) Pub. Date: Jan. 28, 2021

(54) ELECTRICAL CIRCUIT FOR FILTERING A LOCAL OSCILLATOR SIGNAL AND HARMONIC REJECTION MIXER

(71) Applicant: Huawei Technologies Co., Ltd., Shenzhen (CN)

(72) Inventors: Mikko John ENGLUND, Helsinki (FI); Kimmo KOLI, Helsinki (FI)

(21) Appl. No.: 17/069,514

(22) Filed: Oct. 13, 2020

Related U.S. Application Data
(63) Continuation of application No. PCT/EP2018/059561, filed on Apr. 13, 2018.

(51) Int. Cl. H03H 17/02; H03D 7/00

(52) U.S. Cl. CPC H03H 17/02; H03K 2005/00078; H03D 7/00

(57) ABSTRACT

An electrical circuit can have a local oscillator, a first mixer, a second mixer, and a delay element. The first mixer mixes an input signal with a local oscillator signal. The second mixer mixes the input signal with a delayed local oscillator signal, delayed by the delay element. The output signals from the first mixers are combined to form an output signal of the electrical circuit.

### CROSS-REFERENCE TO RELATED APPLICATIONS

This application is a continuation of International Patent Application No. PCT/EP2018/059561, filed on Apr. 13, 2018, the disclosure of which is hereby incorporated by reference in its entirety.

### FIELD

The present disclosure relates to an electrical circuit used to filter a local oscillator signal. The present disclosure also relates to a Finite Impulse Response, FIR, filter and to a receiver that uses the electrical circuit or the FIR filter.

### BACKGROUND

In modulation/demodulation of signals it is often necessary to reduce the out-of-band noise or unwanted tones. A typical source of out-of-band noise is the use of quantized signals in the mixing, where the tones are a result of non-ideal mixing waveforms that generate additional mixing products. A number of techniques exist that can be used to reduce these unwanted effects.

For example, EP2328273 describes a radio frequency (RF) modulator adapted to modify quantisation noise resultant from an interpolator of the RF modulator such that the quantisation noise at a predetermined frequency is reduced.

In applications such as the one described in EP2328273, the harmonic components resulting from the use of a pulse shaped local oscillator (LO) are rejected by having additional signal paths that are properly weighted and summed. The weighting and summing can be done at different parts of the signal chain, in the RF, at the analog baseband, or as a part of the digital post processing. In the RF, the weighting is done by dividing the first amplifier into parts and selecting a proper transconductance for each part. Alternatively, additional basebands can be used to support the needed phases. The weighted phases can then be summed in the analog baseband, or in the digital post processor after analog-to-digital conversion. The harmonic components are rejected upon summing.

### SUMMARY

The inventors found that existing solutions have several problems. Dividing the RF amplifiers into several parts complicates the already challenging task of designing a wideband, low noise, and high linearity amplifier that is required in software defined radio receivers. Additional parasitics, which limit the frequency of operation, cannot be avoided. Alternative solutions implement the weighting and summing in the baseband or as part of the digital post processing. However, the harmonic components are attenuated only after the summing, which means that, for the highest linearity benefit, the summing should be done as early as possible. Furthermore, the additional phases need to be supported up to the summing point, which requires additional hardware and therefore increases the power consumption. Solutions exist that utilize discrete-time techniques, but they suffer from aliasing. A common drawback in the current solutions is that the LO generation circuitry often becomes complicated.

Hence, the inventors have recognized that there is a need for an improved electrical circuit that can provide reduced out-of-band noise and/or unwanted tones in an efficient manner.

Embodiments of the present disclosure provide an improved electrical circuit that can provide an efficient filtering of the local oscillator signal for use in radio frequency receivers and also in other electrical circuits.

In accordance with a first aspect of the present disclosure, an electrical circuit is provided. The electrical circuit can have an input terminal to receive an input signal and an output terminal at which an output signal can be provided. The electrical circuit further comprises a local oscillator, a first mixer, a second mixer, and a delay element. In the electrical circuit, the first mixer is configured to receive an input signal from the input terminal and to mix the input signal with a local oscillator signal from the local oscillator. Also, the second mixer is configured to receive the input signal from the input terminal and to mix the input signal with a delayed local oscillator signal, where the delayed local oscillator signal is the local oscillator signal fed via the delay element to the second mixer. The electrical circuit is configured to combine the output signal from the first mixer with the output signal from the second mixer to form an output signal at the output terminal. Hereby, an electrical circuit is provided that can efficiently handle the non-idealities of a local oscillator (LO) in electronic devices such as receivers or transmitters. This is achieved by the electrical circuit that uses a form of finite impulse response (FIR) filter mixer. For example, in receivers, the electrical circuit can be used to filter harmonic components of a pulse-shaped LO signal, resulting in attenuation of the unwanted harmonic down-conversion products. The electrical circuit can also be used in other applications, such as but not limited to, filtering of the quantization noise or spurious tones of a digitally generated LO signal.

In accordance with a first implementation of the first aspect, at least one additional mixer is configured to receive the input signal from the input terminal and to mix the input signal with a further delayed local oscillator signal. The further delayed local oscillator signal is a local oscillator signal with a delay longer than the delayed local oscillator signal, and the electrical circuit is configured to combine the output signal from the first mixer with the output signal from the second mixer and the output signal from the at least one additional mixer to form an output signal at the output terminal. Hereby a more advanced, but also more complex, electrical circuit is provided that can filter more components. For example, higher order harmonic components can be filtered in a receiver.

In accordance with a second implementation of the first aspect, the electrical circuit comprises at least one additional delay element and is configured to provide the further delayed local oscillator signal by letting the delayed local oscillator signal pass the at least one additional delay element. Hereby the electrical circuit can be designed in a simple manner where a delay element is added to increase the delay of the LO signal for providing a more advanced electrical circuit with more design options.

In accordance with a third implementation of the first aspect, the electrical circuit is configured to weight the input signal from the input terminal before feeding it to at least one of the mixers. The electrical circuit can also be configured to weight an output signal from at least one mixer before combining output signals from different mixers. Hereby, additional design options are made available that can make the design of the electrical circuit fit with a particular application. For example, different harmonics can be filtered with different weights. Advantageously, at least one weight used is configurable to make the electrical circuit more flexible to different applications and use cases. A weight used can be formed by a resistor to enable a straightforward implementation.

In accordance with a fourth implementation of the first aspect, the delay element(s) is/are configured to delay the signal from the oscillator with one clock cycle or an integer fraction of one clock cycle. Hereby an efficient filter implementation of the electrical circuit can be obtained that is useful in many known applications such as receiver circuits for radio frequency signals.

In accordance with a second aspect of the present disclosure, a finite impulse response, FIR, filter for filtering a local oscillator signal is provided. The FIR filter is configured to receive the local oscillator signal to be filtered, and weights of the FIR filter are based on weighted versions of an (time varying and preferably analog) input signal. Hereby a FIR filter structure that is useful for generating a filtered local oscillator signal is provided and which can be used to filter signals in a circuit using a local oscillator to generate signals to be mixed with another signal.

In accordance with a first implementation of the second aspect, the FIR filter is configured to weigh an undelayed version of the local oscillator signal with a first weighted version of the input signal and a first delayed version of the local oscillator signal with a second weighted version of the input signal. Hereby a FIR filter function with weighted input can be achieved, whereby the FIR filter can be tailored to implement different filter functions.

In accordance with a second implementation of the second aspect, the FIR filter is configured to weight a second delayed version of the local oscillator signal with a third weighted version of the input signal, wherein a relative weight for the first weighted and a weight for the third weighted version of the input signal is 1, and a relative weight for the second weighted version of the input signal is the square root of 2. Hereby a FIR filter that is useful for filtering an input signal to a receiver circuit can be obtained.

In accordance with a second implementation of the second aspect, the FIR filter can be configured to filter out at least the 3^{rd} and 5^{th} harmonic of the local oscillator signal. Hereby a FIR filter that is useful for filtering a signal comprising higher order harmonics can be obtained.

The electrical circuit and/or the FIR filter as set out above can advantageously be used for an analogue input signal. The input signal, in some embodiments, can be a radio frequency signal.

In accordance with a third aspect of the disclosure, a receiver comprising the electrical circuit or the FIR filter as set out above is provided. Hereby a receiver with a filter can be provided that improves upon existing receives and which can filter harmonic components of a pulse-shaped LO signal, resulting in attenuation of the unwanted harmonic down-conversion products.

The receiver can be a down-conversion receiver. In particular the receiver can be configured to reject 3rd and 5th harmonics for both an in-phase (I) branch and quadrature (Q) branch of the down-conversion receiver.

Further, the receiver can be configured to apply a relative weight of 1 for the input signal mixed with an undelayed version of the local oscillator signal, to apply a relative weight of the square root of 2 to a first delayed version of the local oscillator signal, and to apply a relative weight of 1 to a second delayed version of the local oscillator signal. Hereby a weighted filter that is useful for the receiver can be obtained.

### BRIEF DESCRIPTION OF THE DRAWINGS

The present disclosure will now be described in more detail, by way of example, and with reference to the accompanying drawings, in which:

FIG. 1 shows an electrical circuit that can filter a local oscillator signal;

FIG. 2 illustrates spectra of the original LO, the effective LO, and the FIR filter response;

FIGS. 3a and 3b show an example implementation in a direct down-conversion receiver; and

FIG. 4 shows different waveforms that can result in the exemplary implementation.

### DETAILED DESCRIPTION

The present disclosure will now be described in detail hereinafter with reference to the accompanying drawings, in which certain embodiments of the present disclosure are shown. The present disclosure may, however, be embodied in many different forms and should not be construed as limited to the embodiments set forth herein; rather, these embodiments are provided by way of example so that this disclosure will be thorough and complete, and will fully convey the scope of the disclosure to those skilled in the art. Like numbers refer to like elements throughout the description.

To improve the filtering of, for example, harmonics of a Local Oscillator (LO) signal, an electrical circuit is provided. The electrical circuit can be formed by a FIR filter configured to filter the LO signal itself. This is implemented using parallel mixers added with delayed version(s) of the original LO, effectively creating a Finite Impulse Response (FIR) filter for the LO waveform. The mixers can be weighted to obtain various filter responses, and the electrical circuit as described herein can have various applications in addition to the harmonic rejection example used herein.

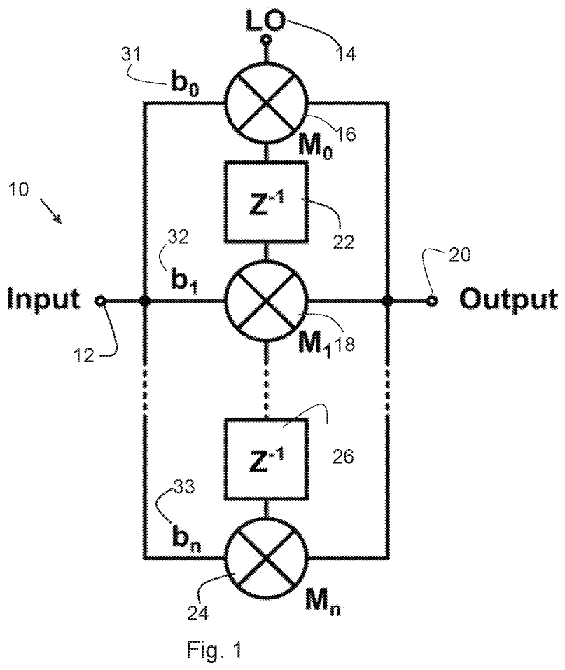

In FIG. 1, an electrical circuit 10 that can implement a FIR filtering of a LO signal is shown. The electrical circuit comprises an input terminal 12. The input terminal 12 can be configured to receive a signal to be mixed with a Local Oscillator, LO, signal. The mixing of the input signal at the input terminal 12 and the local oscillator signal is performed in a first mixer 16.

To simplify the description, the generation of the LO signal is represented by a Local Oscillator, LO, 14. However, how the LO signal is generated is not important, and any device generating a LO signal can be used, including but not limited to an oscillator. The term Local Oscillator whenever used herein should therefore be interpreted in a broad sense as any device capable of generating an LO signal.

The first mixer 16 is connected to the input terminal 12 and to the local oscillator 14. The output from the first mixer 16 is connected to an output terminal 20.

In order to filter, for example, harmonic components in the generated oscillator signal, the signal at the output terminal can be combined with a delayed version of the oscillator signal mixed with the input signal. This can be obtained by feeding the LO signal via a delay element 22 to a second mixer 18. The second mixer 18 is configured to mix the delayed version of the LO signal with the input signal. Thus, the second mixer 18 is connected to the input terminal and to the output from the delay element 22.

The electrical circuit can in accordance with some embodiments have additional mixers 24 configured to mix the input signal with further delayed versions of the oscillator signal. The signal formed by the additional mixers 24 can be combined with the other output signals from the first mixer and the second mixer at the output terminal. The delayed version(s) of the oscillator signal can be generated by a single delay element 22 or additional delay elements 26 can be provided in the electrical circuit 10.

The structure of the electrical circuit 10 can be seen as a FIR filter for the oscillator signal where the delayed version(s) of the local oscillator signal is/are mixed with the input signal to form an output signal.

The delayed versions of the LO signal can be mixed with weighted versions of the input signal. For this purpose, weights can be provided at the respective paths between the input terminal and the different mixers. For example, in the embodiment shown in FIG. 1, weights 31, 32 and 33 are provided before the mixers 16, 18 and 24. The weights for weighting the input signal can be provided before the mixer as shown in FIG. 1. In another embodiment, the weights can be provided after the mixers before combining the signals at the output terminal.

Hereby, a finite impulse response, FIR, filter for filtering a local oscillator signal is provided, where the FIR filter is configured to receive the local oscillator signal to be filtered, and wherein weights of the FIR filter are based on weighted versions of an input signal. The weights can for example be implemented using resistors. The value of the resistors can be configurable to allow adjustment of the filter weights to suit a particular application.

In such a FIR filter configuration, the filter can be configured to weigh an undelayed version of the local oscillator signal with a first weighted version of the input signal and a first delayed version of the local oscillator signal with a second weighted version of the input signal. For example, in the embodiment of FIG. 1, the first weighted version is weighted by a weight 31 having a weight b₀, and the second weighted version is weighted by a weight 32 having a weight b₁. In a configuration with three mixers using three delayed versions of the local oscillator signal, three different weights can be provided. The relative weights for the three different weights can then be:

b₀=1,b₁=√2,b₂=1

Such a selection of weights 31, 32, and 33 can advantageously be used to filter out at least the 3^{rd} and 5^{th} harmonics of the local oscillator signal.

As is implied by FIG. 1, additional mixer cores are added in parallel to the first mixer 16 and the second mixer 18. The number of mixers and delayed versions of the oscillator signal mixed with the input signal by the respective mixer can depend upon the application. Each mixer input (or output or both input and output) is weighted with corresponding coefficient bx. The additional mixers are driven with increasingly delayed version of the original local oscillator signal. In one embodiment, the LO signal is delayed (between two successive mixers) by one sampling clock cycle t_s. In other words, each delay element 22, 24, etc. is configured to delay the LO signal by one such sampling clock cycle t_s. The sampling clock cycle is the LO clock cycle t_LO divided by an integer number such as 8, which is used in the following as an example.

In order to obtain harmonic rejection for the 3rd and 5th harmonics, three mixers can be used for FIG. 1, which would mean a first mixer 16 and two additional mixer cores 18 and 24. If the relative weighting of coefficients is selected as above, i.e.:

b₀=1,b₁=√2,b₂=1

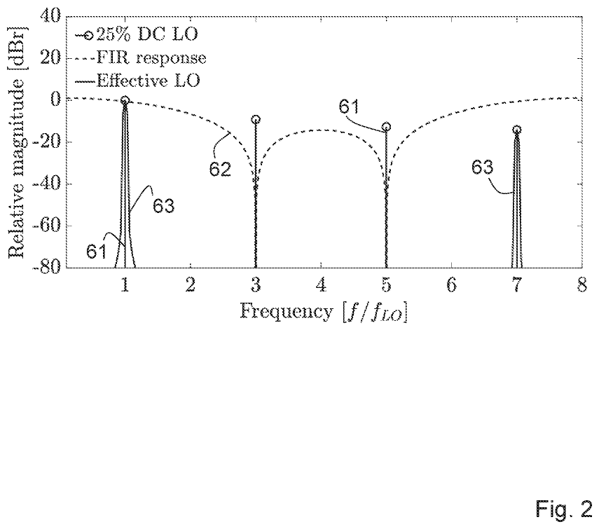

a filtering response 62 shown in FIG. 2 is applied to the LO signal. In FIG. 2, the original LO signal is a 25% duty-cycle (DC) pulse wave 61, which contains odd harmonics in addition to the desired fundamental tone. In the filtered LO signal 63, the 3rd and the 5th harmonic of the LO signal are cancelled. In a practical application, the attenuation is limited by how accurately the coefficients can be implemented.

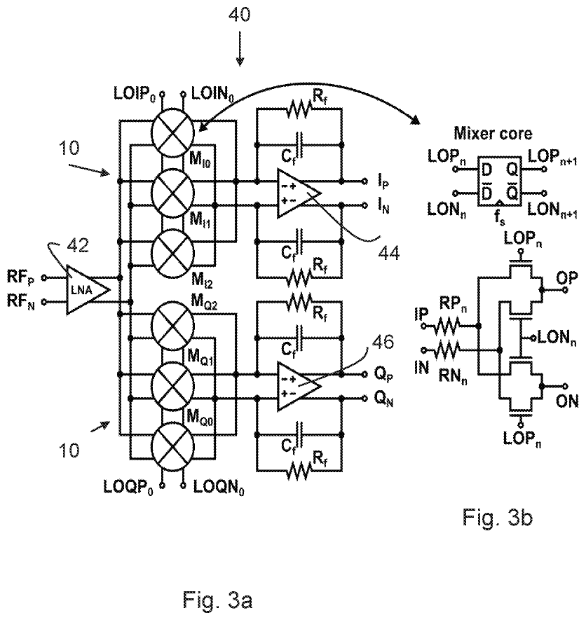

An example application when using an electrical circuit as described above can be in a direct down-conversion receiver. Such a receiver 40 is shown in FIG. 3a. In the exemplary embodiment shown in FIG. 3a, an electrical circuit 10 according to the embodiment set out above in conjunction with FIG. 1 is used for the in-phase (I) and quadrature (Q) branches, respectively of the receiver 40.

The electrical circuits 10 can have three mixers each to obtain harmonic rejection for the 3rd and 5th harmonic of the LO signal. The relative weighting for each branch can then be set as above.

In FIG. 3b, the respective mixers of an electrical circuit 10 in FIG. 3a are depicted. In FIG. 3b, the respective Positive Local Oscillator signals (LOPn) and the respective negative Local oscillator signals (LONn) are implemented using resistors RPn and RNn, (n=0,1,2), whose currents are then summed at the virtual ground of the baseband transconductance amplifier.

Thus, a receiver 40, in particular a direct down-conversion receiver can be provided, which comprises and makes beneficial use of the electrical circuit 10 outlined in FIG. 1. The direct down-conversion receiver 40 of FIG. 3a comprises an input low-noise amplifier (LNA) 42 to which the input signal to the receiver 40 is fed. The input signal is typically a radio frequency analogue signal in the case of a direct down-conversion receiver 40. An aspect to consider is then that the absolute value of the resistance loading the low-noise amplifier (LNA) at any time should be kept constant to avoid impedance level modulation. Further, the output from the electrical circuits 10 for the respective I and Q branches can be connected to amplifiers 44 and 46, respectively for forming the respective output signals for the I and Q branches, i.e. Ip, In and Qp, Qn.

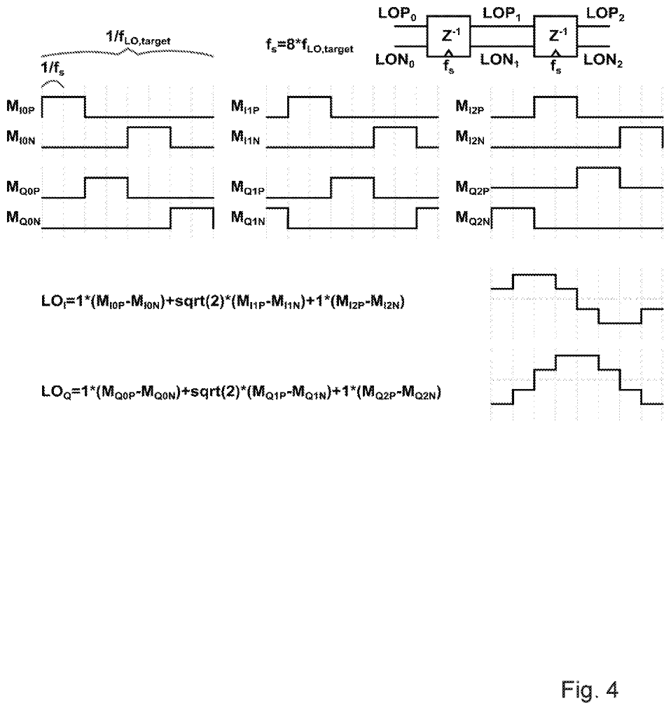

In accordance with one embodiment, the sampling rate fs is 8 times the target LO frequency f_ (LO,target). Such a scenario is shown in FIG. 4. In FIG. 4 the positive (MInP, MQnP) and negative (MInN, MQnN) LO waveforms for each mixer MIn, MQn (n=0,1,2) for the I branch and Q branch respectively are shown. Also, FIG. 4 shows the effective LO waveforms for I and Q branch LOI and LOQ after summing of the output signals from the mixers.

The FIR filtering described herein for harmonic rejection in radio frequency receivers minimizes the length of the additional paths and therefore the number of additional components. This will in turn reduce any additional power consumption. The receiver can be implemented without having to make any alterations to the sensitive RF amplifier. Also, the weighting and summing is done at an early stage in the receiver chain, relaxing the linearity requirement of the following stages due to harmonic products.

Further, the LO signal generation can be as simple as in traditional pulse driven mixer arrangements without harmonic rejection. Also, the input signal does not need to be sampled, which avoids aliasing and problems resulting from aliasing.

Also, in contrast to current solutions, the LO waveform can be selected more freely. The duty-cycle does not have to be exact. In addition to the 25% DC pulse LO signal used as an example above, any two-level signal may be utilized, as long as it can be represented within the limits of the sampling frequency. Examples of this include pulse-width modulated or delta-sigma shaped LO waveforms. Using an LO waveform which has more than two levels is also possible, provided that parallel mixer cores are added to account for the added levels.

The electrical circuit and the FIR filter as described herein has been described above in an application where an analogue RF signal is received and where the aim is to reject harmonics. However, the described circuit and filter are very versatile and can easily be modified to meet other needs. This in contrast to pre-existing solutions for harmonic rejection where the solutions are fixed and have a single purpose. Thus, the electrical circuit and the FIR filter described herein can be used in many different applications and is easy to scale as the filter length and response are easily adjusted by adding more mixers and mix the input signal with further delayed LO signals and also by adjusting the weights for the different mixed signals. Further, while the electrical circuit has been described as a receiving circuit configured to receive an analogue RF signal and mix the RF signal with a digital LO signal, other configurations are possible and the input signal does not need to be an RF signal or an analogue signal.

As another field of application, the electrical circuit and the FIR filter can be used for quantization noise filtering. For example, a digital LO signal can be filtered from quantization noise using the electrical circuit and filter as described herein. The filter response can be configured to have lowpass characteristics or bandpass characteristics. In another embodiment the filter response can be configured as notch filter to target specific frequencies.

What is claimed is:

1. An electrical circuit, the electrical circuit comprising:
an input terminal;
an output terminal;
a local oscillator;
a first mixer;
a second mixer; and
a delay element, wherein:
the first mixer is configured to receive an input signal from the input terminal and to mix the input signal with a local oscillator signal from the local oscillator,
the second mixer is configured to receive the input signal from the input terminal and to mix the input signal with a delayed local oscillator signal,
the delay element configured to receive the local oscillator signal, and to delay the received local oscillator signal to provide the delayed local oscillator signal to the second mixer, and
the electrical circuit is configured to combine an output signal from the first mixer with an output signal from the second mixer to form an output signal at the output terminal.

2. The electrical circuit according to claim 1, the electrical circuit further comprising at least one additional mixer,
wherein the at least one additional mixer is configured to receive the input signal from the input terminal and to mix the input signal with a further delayed local oscillator signal,
wherein the further delayed local oscillator signal is a local oscillator signal with a delay longer than the delayed local oscillator signal, and
wherein the electrical circuit is configured to combine the output signal from the first mixer with the output signal from the second mixer and the output signal from the at least one additional mixer to form the output signal at the output terminal.

3. The electrical circuit according to claim 2, wherein the electrical circuit comprises at least one additional delay element and is configured to provide the further delayed local oscillator signal by letting the delayed local oscillator signal pass the at least one additional delay element.

4. The electrical circuit according to claim 1, wherein the electrical circuit is configured to weight the input signal from the input terminal before feeding it to at least one of the first mixer or the second mixer.

5. The electrical circuit according to claim 1, wherein the electrical circuit is configured to weight the output signal from at least one of the first mixer or the second mixer before combining the output signal from the first mixer and the output signal from the second mixer.

6. The electrical circuit according to claim 4, wherein at least one weight used for weighting is configurable.

7. The electrical circuit according to claim 4, the electrical circuit comprising a resistor configured to provide the weight.

8. The electrical circuit according to any claim 1, wherein the delay element is configured to delay the local oscillator signal with one clock cycle or an integer fraction of one clock cycle.

9. A finite impulse response (FIR) filter for filtering a local oscillator signal, the FIR filter being configured to receive the local oscillator signal to be filtered, and wherein weights of the FIR filter are based on weighted versions of an input signal.

10. The FIR filter according to claim 9, wherein the FIR is configured to weigh an undelayed version of the local oscillator signal with a first weighted version of the input signal and a first delayed version of the local oscillator signal with a second weighted version of the input signal.

11. The FIR filter according to claim 10, wherein the FIR is configured to weigh a second delayed version of the local oscillator signal with a third weighted version of the input signal, wherein a relative weight for the first weighted and a weight for the third weighted version of the input signal is 1 and a relative weight for the second weighted version of the input signal is the square root of 2.

12. The FIR filter according to claim 8, wherein the FIR filter is configured to filter out at least the 3rd and 5th harmonic of the local oscillator signal.

13. The electrical circuit according to claim 1, wherein the input signal is an analogue input signal.

14. The electrical circuit according to claim 1, wherein the input signal is a radio frequency signal.

15. The electrical circuit according claim 1, wherein the local oscillator signal is a digital signal.

16. A receiver, the receiver comprising the electrical circuit according to claim 1.

17. The receiver according to claim 16, wherein the receiver is a down-conversion receiver.

18. The receiver according to claim 17, wherein the receiver is configured to reject 3rd and 5th harmonics for both an in-phase branch and a quadrature branch of the down-conversion receiver.

19. The receiver according to claim 17, wherein the receiver is configured to apply a relative weight of 1 for the input signal mixed with an undelayed version of the local oscillator signal, to apply a relative weight of square root of 2 to a first delayed version of the local oscillator signal and to apply a relative weight of 1 to a second delayed version of the local oscillator signal.
